(19) United States
(12) Patent Application Publication
(10) Pub. No.: US 2026/0026177 A1
(43) Pub. Date: Jan. 22, 2026

(54) DISPLAY PANEL, METHOD FOR MANUFACTURING THE SAME, AND DISPLAY DEVICE

(71) Applicant: HKC CORPORATION LIMITED, Shenzhen (CN)

(72) Inventors: QIN LIANG, Shenzhen (CN); Yangling TANG, Shenzhen (CN); Zhisheng XIE, Shenzhen (CN); Zhi YANG, Shenzhen (CN); Lidan YE, Shenzhen (CN)

(21) Appl. No.: 19/262,092

(22) Filed: Jul. 8, 2025

(30) Foreign Application Priority Data
Jul. 17, 2024 (CN) 202410957579.4

(51) Int. Cl. H10H 29/854; H10H 29/01; H10H 29/37

(52) U.S. Cl. CPC H10H 29/854; H10H 29/012; H10H 29/37

(57) ABSTRACT

A display panel, a method for manufacturing a display panel, and a display device are disclosed. The display panel includes a substrate, multiple partition structures, multiple light-emitting elements, and a first inorganic encapsulation layer. Each partition structure includes a pixel defining layer, a conductive layer, and an insulating layer stacked in sequence. The insulating layer includes a first insulating portion and a second insulating portion. The second insulating portion is arranged on a side of the conductive layer facing away from the pixel defining layer. The first insulating portion is arranged on a side of the second insulating portion facing away from the conductive layer. An orthographic projection of the first insulating portion on the substrate at least partially overlaps an orthographic projection of the second insulating portion on the substrate.

### CROSS-REFERENCE TO RELATED APPLICATIONS

This application claims the priority and benefit of Chinese patent application number 2024109575794, titled “Display Panel, Method for Manufacturing the Same, and Display Device” and filed Jul. 17, 2024 with China National Intellectual Property Administration, the entire contents of which are incorporated herein by reference.

### TECHNICAL FIELD

The present application relates to the field of display technology, and more particularly relates to a display panel, a method for manufacturing the same, and a display device.

### BACKGROUND

The description provided in this section is intended for the mere purpose of providing background information related to the present application but does not necessarily constitute prior art.

In the field of display panels, under the Fine Metal Mask (FMM)-less Technology, a partition structure is formed on the substrate by stacking a pixel defining layer, a conductive layer, and an insulating layer, thereby achieving the purpose of confining the deposition region of the vapor-deposited film layers, enabling a more cost-effective option for product development.

As shown in FIG. 1, the design of the partition structure 120 resembles a mushroom-shaped configuration, where the conductive layer corresponds to the mushroom stem and the insulating layer corresponds to the mushroom cap positioned above the stem. However, the structural features between the conductive layer and the insulating layer are likely to affect the reliability of the encapsulation. Therefore, this remains an issue that urgently needs to be addressed.

### SUMMARY

One purpose of the present application is to provide a display panel, a method for manufacturing the same, and a display device that eliminate encapsulation closure holes and improve the encapsulation reliability.

The present application discloses a display panel, including a substrate, a plurality of partition structures, a plurality of light-emitting elements, and a first inorganic encapsulation layer. Each of the partition structures includes a pixel defining layer, a conductive layer, and an insulating layer that are stacked in sequence. The plurality of pixel defining layers are arranged on the substrate at intervals. A pixel opening is formed between every two adjacent pixel defining layers, thereby forming a plurality of pixel openings. The plurality of light-emitting elements are respectively disposed within the plurality of pixel openings in one-to-one correspondence. The first inorganic encapsulation layer is disposed on and covers the side of the light-emitting elements and the partition structures facing away from the substrate. The insulating layer includes a first insulating portion and a second insulating portion. The second insulating portion is disposed on the side of the conductive layer facing away from the pixel defining layer. The first insulating portion is disposed on the side of the second insulating portion facing away from the conductive layer. An orthographic projection of the first insulating portion on the substrate at least partially overlaps an orthographic projection of the second insulating portion on the substrate.

In some embodiments, the first insulating portion includes a first sub-insulating portion and a second sub-insulating portion which are arranged on the second insulating portion and are spaced apart from each other. An orthographic projection of the first sub-insulating portion on the substrate partially overlaps an orthographic projection of the second insulating portion on the substrate. An orthographic projection of the second sub-insulating portion on the substrate partially overlaps an orthographic projection of the second insulating portion on the substrate. The first sub-insulating portion, the second sub-insulating portion, and the second insulating portion jointly form a groove structure.

In some embodiments, the cross-sections of the first sub-insulating portion and the second sub-insulating portion in a thickness direction of the substrate are each an upright trapezoidal structure. The cross-section of the second insulating portion in the thickness direction of the substrate is an inverted trapezoidal structure.

In some embodiments, the thickness of the second insulating portion is greater than the thickness of the first sub-insulating portion or the thickness of the second sub-insulating portion. The thickness of the first sub-insulating portion is equal to the thickness of the second sub-insulating portion. Let the thickness of the second insulating portion be H, and let the thickness of each of the first sub-insulating portion and the second sub-insulating portion be h, then h≥½H.

In some embodiments, the insulating layer has a T-shaped structure. The first insulating portion has an upright trapezoidal cross-section in the thickness direction of the substrate. The second insulating portion has an inverted trapezoidal cross-section in the thickness direction of the substrate.

In some embodiments, the second insulating portion includes a first surface and a second surface that are oppositely arranged. The conductive layer includes a third surface and a fourth surface that are oppositely arranged. The third surface of the conductive layer is attached to the pixel defining layer. The fourth surface of the conductive layer is attached to the second surface of the second insulating portion. The first surface of the second insulating portion is attached to the first insulating portion. Along the direction in which each partition structure is arranged, the width of the second surface of the second insulating portion is equal to the width of the fourth surface of the conductive layer.

In some embodiments, each of the light-emitting elements includes an anode layer, a light-emitting layer, and a cathode layer that are stacked in sequence. The anode layer includes a first end and a second end that face away from each other. The pixel defining layer includes a first portion and a second portion that are stacked in sequence. One side of the first portion extends and overlaps the first end or the second end of the anode layer to form an overlapping portion. The overlapping portion combines with the second portion to form a step structure. The light-emitting layer and the cathode layer each partially overlap the step structure.

In some embodiments, the width of the second portion is greater than the width of the second insulating portion of the insulating layer.

The present application further discloses a method for manufacturing a display panel, which is used for the display panel as described above, and includes the following steps:
providing a substrate;
forming spaced anode layers on the substrate;
forming a pixel defining layer between two adjacent anode layers, so that a pixel opening is formed between the two adjacent pixel defining layers;
forming a conductive layer on the pixel defining layer in sequence;
forming a bottom shape structure of an insulating layer on the conductive layer using a template layer;
forming an insulating layer on the bottom shape structure, where the pixel defining layer, the conductive layer, and the insulating layer jointly form a partition structure;
forming a light-emitting layer and a cathode layer in sequence at each pixel opening, so that the anode layer, the light-emitting layer, and the cathode layer jointly form a light-emitting element;
forming a first inorganic encapsulation layer on the side of the light-emitting element and the partition structure facing away from the substrate;
S9: forming an organic encapsulation layer over the first inorganic encapsulation layer to obtain a fully encapsulated display panel.

The present application further discloses a display device including the above-described display panel.

Compared with the problem in the related art in which closure holes are likely to form in the regions on both sides of the partition structure during the encapsulation of the first inorganic encapsulation layer, the insulating layer of the partition structure in the present application includes a first insulating portion and a second insulating portion. The second insulating portion is disposed on the side of the conductive layer facing away from the pixel defining layer, and the first insulating portion is disposed on the side of the second insulating portion facing away from the conductive layer. The height of the horizontal plane on which the lower surface of the first insulating portion is located is higher than the height of the horizontal plane on which the second insulating portion is located. In the direction in which each partition structure is arranged, the width of the first insulating portion is greater than the width of the second insulating portion. Thus, the first insulating portion and the second insulating portion jointly form an open cavity therebetween in the direction perpendicular to the substrate, that is, the height of the original horizontal plane of the insulating layer is raised, so that the distance between the insulating layer and the pixel defining layer is increased. In this way, the interval measured from the film surface of the vapor-deposited light-emitting layer and cathode layer to the insulating layer is increased, so that the encapsulation surface of the first inorganic encapsulation layer on the cathode layer and the encapsulation surface covering the lower surface of the first insulating portion will not contact each other to form a closed internal hole, thereby improving the reliability of the encapsulation.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative efforts. In the drawings:

FIG. 1 is a schematic cross-sectional view of a display panel according to the related art.

FIG. 2 is a schematic block diagram of a display device provided in the present application.

FIG. 3 is a schematic diagram of a display panel provided in the present application.

FIG. 4 is a schematic cross-sectional view taken along line A-A′ of FIG. 3.

FIG. 5 is a schematic diagram of a partition structure on the display panel according to a first embodiment of the present application.

FIG. 6 is a partially enlarged schematic view of portion B shown in FIG. 4.

FIG. 7 is a flowchart of a method of manufacturing a display panel provided in the present application.

FIG. 8 is a schematic diagram of film layers of a display panel according to a second embodiment of the present application.

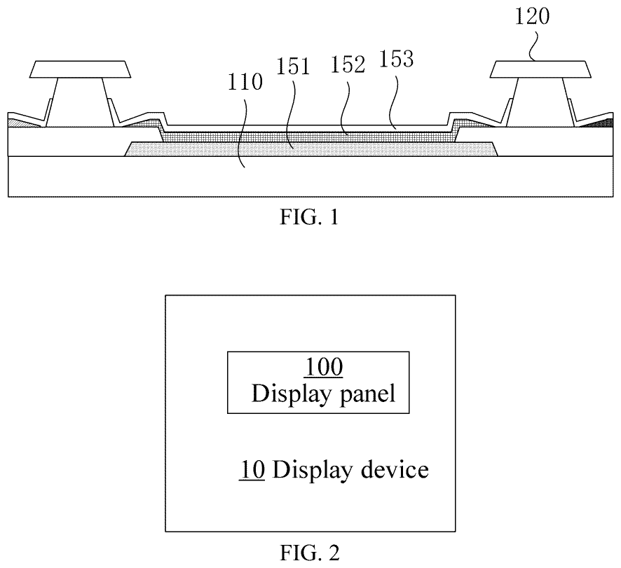

In the drawings: 10, display device; 100, display panel; 110, substrate; 120, partition structure; 121, pixel defining layer; 122, conductive layer; 123, insulating layer; 124, first insulating portion; 125, second insulating portion; 126, first sub-insulating portion; 127, second sub-insulating portion; 128, first portion; 129, second portion; 130, overlapping portion; 131, first inclined surface; 132, second inclined surface; 133, third inclined surface; 134, fourth inclined surface; 135, fifth inclined surface; 136, six inclined surface; 137, seventh inclined surface; 138, eighth inclined surface; 139, first surface; 140, second surface; 141, third surface; 142, fourth surface; 143, encapsulation corner; 144, step structure; 145, step corner; 150, light-emitting element; 151, anode layer; 152, light-emitting layer; 153, cathode layer; 154, first end; 155, second end; 160, groove structure; 170, first inorganic encapsulation layer; 171, partition encapsulation area; 172, hole; 180, organic encapsulation layer.

### DETAILED DESCRIPTION OF EMBODIMENTS

It should be understood that the terms used herein, the specific structures arrangements, and the functional details disclosed herein are merely representative for describing some specific embodiments, but the present application may be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “second orientation”, and “first orientation”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

As used herein, the term “upright trapezoid” refers to a trapezoidal shape that is positioned upright, such that the top base is relatively shorter and the bottom base is relatively longer. This orientation results in a structure that appears wider at the bottom and narrower at the top when viewed in cross section. In contrast, an “inverted trapezoid” is a trapezoidal shape positioned upside down, with the top base being relatively longer and the bottom base being relatively shorter, thereby creating a structure that is wider at the top and narrower at the bottom. These definitions are used throughout the present disclosure to describe the cross-sectional profiles of various structural layers in the display panel.

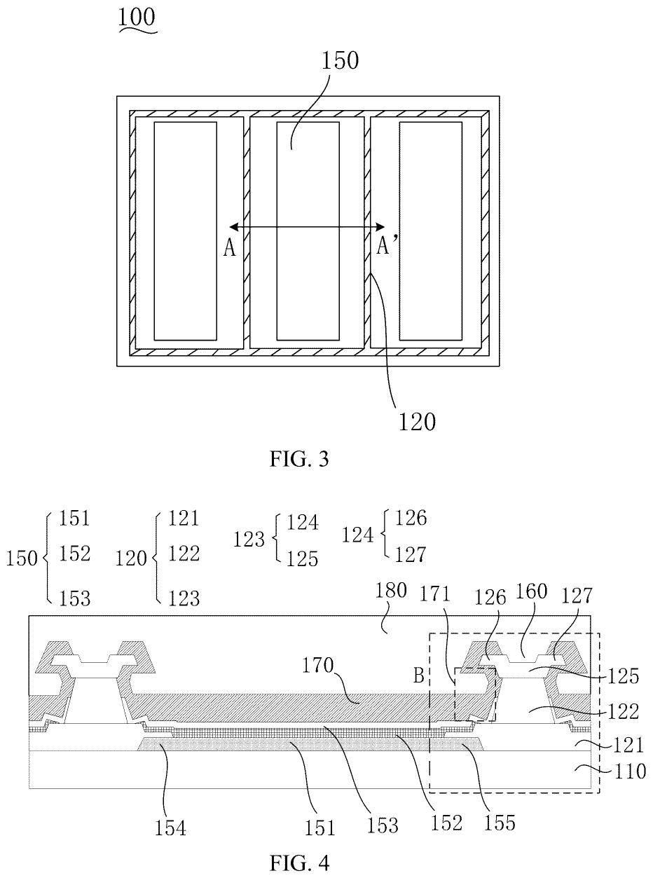

FIG. 2 is a schematic block diagram of a display device provided in the present application. FIG. 3 is a schematic diagram of a display panel provided in the present application. FIG. 4 is a schematic cross-sectional view taken along line A-A′ of FIG. 3. As shown in FIGS. 2 to 4, the present application discloses a display device 10, which includes a display panel 100. The display panel 100 includes a substrate 110, a plurality of partition structures 120, a plurality of light-emitting elements 150, and a first inorganic encapsulation layer 170. Each of the partition structures 120 includes a pixel defining layer 121, a conductive layer 122, and an insulating layer 123 that are stacked in sequence, thus obtaining a plurality of pixel defining layers 121. The plurality of pixel defining layers 121 are spaced apart on the substrate 110. A pixel opening is formed between two adjacent pixel defining layers 121, thus obtaining a plurality of pixel openings. The plurality of light-emitting elements 150 are respectively disposed within the plurality of pixel openings in one-to-one correspondence. The first inorganic encapsulation layer 170 is disposed on and covers the side of the plurality of light-emitting elements 150 and the partition structures 120 facing away from the substrate. The insulating layer 123 includes a first insulating portion 124 and a second insulating portion 125. The second insulating portion 125 is disposed on the side of the conductive layer 122 facing away from the pixel defining layer 121. The first insulating portion 124 is disposed on the side of the second insulating portion 125 facing away from the conductive layer 122. The height of the horizontal plane on which the lower surface of the first insulating portion 124 is located is higher than the height of the horizontal plane on which the lower surface of the second insulating portion 125 is located. An orthographic projection of the first insulating portion 124 on the substrate 110 at least partially overlaps that of the second insulating portion 125 on the substrate 110.

Compared with the problem in the related art in which closure holes are likely to form in the regions on both sides of the partition structure 120 during the encapsulation of the first inorganic encapsulation layer 170, the insulating layer 123 of the partition structure 120 in the present application includes a first insulating portion 124 and a second insulating portion 125. The second insulating portion 125 is disposed on the side of the conductive layer 122 facing away from the pixel defining layer 121, and the first insulating portion 124 is disposed on the side of the second insulating portion 125 facing away from the conductive layer 122. The orthographic projection of the first insulating portion 124 on the substrate 110 at least partially overlaps that of the second insulating portion 125, that is, the height of the horizontal plane on which the lower surface of the first insulating portion 124 is located is higher than the height of the horizontal plane on which the second insulating portion 125 is located. The lower surface of the first insulating portion 124 and the lower surface of the second insulating portion 125 form an open cavity in the direction perpendicular to the substrate 110, that is, the height of the original horizontal plane of the insulating layer 123 is raised, so that the distance between the insulating layer 123 and the pixel defining layer 121 is increased. In this way, the interval measured from the film surface of the vapor-deposited light-emitting layer 152 and cathode layer 153 to the insulating layer 123 is increased, so that the encapsulation surface of the first inorganic encapsulation layer 170 on the cathode layer 153 and the encapsulation surface covering the lower surface of the first insulating portion 124 will not contact each other to form a closed internal hole, thereby improving the reliability of the encapsulation.

The present application will be described in detail below with reference to the accompanying drawings and some optional embodiments.

### First Embodiment

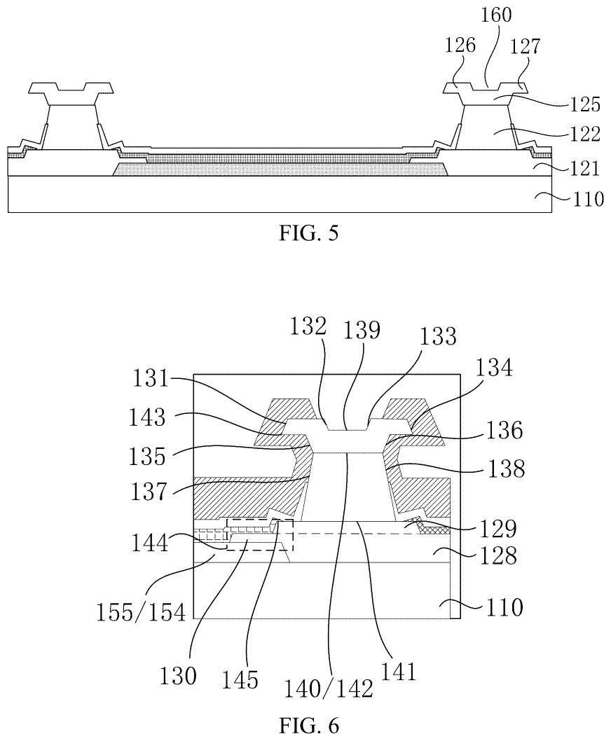

FIG. 5 is a schematic diagram of a partition structure on a display panel according to a first embodiment of the present application. FIG. 6 is a partially enlarged schematic view of portion B shown in FIG. 4. As shown in FIG. 5, also with reference to FIGS. 4 and 6, specifically the first insulating portion 124 includes a first sub-insulating portion 126 and a second sub-insulating portion 127, which are spaced apart from each other on the second insulating portion 125. An orthographic projection of the first sub-insulating portion 126 on the substrate 110 partially overlaps an orthographic projection of the second insulating portion 125 on the substrate 110. An orthographic projection of the second sub-insulating portion 127 on the substrate 110 partially overlaps an orthographic projection of the second insulating portion 125 on the substrate 110. That is, the first sub-insulating portion 126 and the second sub-insulating portion 127 are each partially attached to the second insulating portion 125 and are respectively located at both ends of the second insulating portion 125. The first sub-insulating portion 126, the second sub-insulating portion 127, and the second insulating portion 125 together form an insulating layer 123 with a horn-shaped cross-sectional structure. In this way, the distance between the first sub-insulating portion 126 and the pixel defining layer 121, as well as the distance between the second sub-insulating portion 127 and the pixel defining layer 121, are both increased, so that the first inorganic encapsulation layer 170 in the partition encapsulation area 171 does not contact itself to form a closed internal hole.

In addition, the first sub-insulating portion 126, the second sub-insulating portion 127, and the second insulating portion 125 jointly form a groove structure 160. After completing the encapsulation of the first inorganic encapsulation layer 170, an organic encapsulation layer 180 is further formed above the first inorganic encapsulation layer 170 for encapsulation. The presence of the groove structure 160 can enhance the encapsulation adhesion of the subsequent organic encapsulation layer 180.

The cross-sections of the first sub-insulating portion 126 and the second sub-insulating portion 127 in the thickness direction of the substrate 110 are each in an upright trapezoidal shape. The cross-section of the second insulating portion 125 in the thickness direction of the substrate 110 is in an inverted trapezoidal shape. As shown in FIG. 6, the first sub-insulating portion 126 includes a first inclined surface 131 and a second inclined surface 132 disposed opposite to each other. The second sub-insulating portion 127 includes a third inclined surface 133 and a fourth inclined surface 134 disposed opposite to each other. The second insulating portion 125 includes a fifth inclined surface 135 and a sixth inclined surface 136 disposed opposite to each other. When the first inorganic encapsulation material is deposited to form the first inorganic encapsulation layer 170, inclined encapsulation adhesion surfaces can be formed on the first inclined surface 131, the fourth inclined surface 134, the fifth inclined surface 135, and the sixth inclined surface 136. This results in a relatively strong encapsulation adhesion force between the encapsulation material and the insulating layer 123.

In addition, referring to FIGS. 5 and 6, the conductive layer 122 includes a seventh inclined surface 137 and an eighth inclined surface 138 disposed opposite to each other. The fifth inclined surface 135 of the second insulating portion 125 combines with the seventh inclined surface 137 of the conductive layer 122 so that the path of the surface to be encapsulated formed in the partition encapsulation area 171 is relatively tortuous. In this way, the first inorganic encapsulation layer 170 can also form a relatively tortuous encapsulation surface at this position. This increases the spacing between the encapsulation surface at this position and the encapsulation surface corresponding to the cathode layer 153 below, further avoiding the problem of closure holes.

The second insulating portion 125 further includes a first surface 139 and a second surface 140 disposed opposite to each other. An extended end of the first surface 139 is connected to one end of the second surface 140 through the fifth inclined surface 135. The other extended end of the first surface 139 is connected to the other end of the second surface 140 through the sixth inclined surface 136. The conductive layer 122 further includes a third surface 141 and a fourth surface 142 disposed opposite to each other. One end of the third surface 141 is connected to one end of the fourth surface 142 through the seventh inclined surface 137. The other end of the third surface 141 is connected to the other end of the fourth surface 142 through the eighth inclined surface 138. The third surface 141 of the conductive layer 122 is attached to the pixel defining layer 121. The fourth surface 142 of the conductive layer 122 is attached to the second surface 140 of the second insulating portion 125. The first surface 139 of the second insulating portion 125 is attached to the first insulating portion 124. In the direction in which the partition structure 120 is arranged, the width of the second surface 140 of the second insulating portion 125 is equal to the width of the fourth surface 142 of the conductive layer 122. As a result, the encapsulation surface formed between the fifth inclined surface 135, the second surface 140, the fourth surface 142, and the seventh inclined surface 137 is smooth. This avoids the formation of acute-angled gaps between the second surface 140 and the fourth surface 142, which could make it difficult to encapsulate the first inorganic encapsulation layer 170 at the angled gap, thereby making the encapsulation by the first inorganic encapsulation layer 170 more complete.

The thickness of the second insulating portion 125 is greater than the thickness of the first sub-insulating portion 126 or the thickness of the second sub-insulating portion 127. The thickness of the first sub-insulating portion 126 is equal to the thickness of the second sub-insulating portion 127. Let the thickness of the second insulating portion 125 be H, and let the thickness of each of the first sub-insulating portion 126 and the second sub-insulating portion 127 be h, then h≥½H. After stacking in this way, the distance from the horizontal plane of the first sub-insulating portion 126 or the second sub-insulating portion 127 to the pixel defining layer 121 is relatively larger, which is more favorable for the encapsulation of the first inorganic encapsulation layer 170 in the partition encapsulation layer. The overall thickness of the partition structure 120 is 1.4 μm˜2 μm, and the thickness of the insulating layer 123 is 0.4 μm˜1 μm. The design can be made depending on the actual product, and no specific limitation is made here. Furthermore, the thickness of the first sub-insulating portion 126 and the thickness of the second sub-insulating portion 127 can also be set to be equal to the thickness of the second insulating portion 125, so that they can be formed by a single deposition process, making the operation simple.

In addition, the overlapping area of the first sub-insulating portion 126 and the second insulating portion 125 is equal to ½ of the area of the orthographic projection of the first sub-insulating portion 126 on the substrate 110. The overlapping area of the second sub-insulating portion 127 and the second insulating portion 125 is also equal to ½ of the area of the orthographic projection of the second sub-insulating portion 127 on the substrate 110. This ensures the stability of the first sub-insulating portion 126 and the second sub-insulating portion 127, while also allowing the first inorganic encapsulation layer 170 to have a relatively longer encapsulation path in the first sub-insulating portion 126 and the second sub-insulating portion 127, increasing the path for moisture intrusion, thereby ensuring the encapsulating effect of the light-emitting element 150.

As shown in FIG. 4 and in combination with FIG. 6, each light-emitting element 150 includes an anode layer 151, a light-emitting layer 152, and a cathode layer 153 stacked in sequence. The anode layer 151 includes a first end 154 and a second end 155, which are facing away from each other. The pixel defining layer 121 includes a first portion 128 and a second portion 129 stacked in sequence. One side of the first portion 128 extends and overlaps the first end 154 or the second end 155 of the anode layer 151 to form an overlapping portion 130. The overlapping portion 130 combines with the second portion 129 to form a step structure 144. In this way, the slope can be reduced through the step structure 144 when vapor-depositing the light-emitting layer 152, and when the cathode layer 153 is deposited, the slope at the corresponding step structure 144 above the light-emitting layer 152 is also reduced. The step structure 144 reduces the stacking height of the films at the edge of the pixel defining layer 121, lowering the encapsulation height of the first inorganic encapsulation layer 170 at this location, further increasing the encapsulation spacing of the first inorganic encapsulation layer 170 in the partition encapsulation area 171 thus avoiding the occurrence of a closure hole.

Moreover, the width of the second portion 129 is larger than the width of the first insulating portion 124 of the insulating layer 123, widening the encapsulation length at the step structure 144, so that the step corner 145 of the step structure 144 is staggered with the encapsulation corner 143 formed by the first inclined surface 131 of the first insulating portion. If the step corner 145 and the encapsulation corner 143 are not staggered but are at opposite positions, then after the first inorganic encapsulation layer 170 is encapsulated at these two positions, it is easy to reduce the encapsulation space of the partition encapsulation area 171, making it more likely for the first inorganic encapsulation layer 170 to form a closure hole in the partition encapsulation area 171.

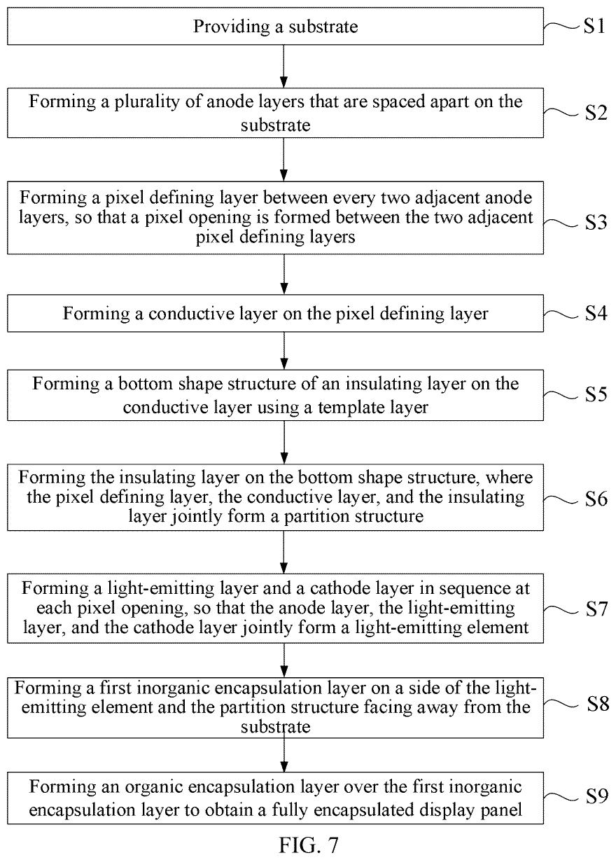

FIG. 7 is a flowchart of a method for manufacturing a display panel provided by this application. As shown in FIG. 7, this application further discloses a method for manufacturing a display panel, which is used for manufacturing the display panels described above, and includes the following steps:
S1: providing a substrate;
S2: forming spaced anode layers on the substrate;
S3: forming a pixel defining layer between two adjacent anode layers, so that a pixel opening is formed between the two adjacent pixel defining layers;
S4: forming a conductive layer on the pixel defining layer in sequence;
S5: forming a bottom shape structure of an insulating layer on the conductive layer using a template layer;
S6: forming an insulating layer on the bottom shape structure, where the pixel defining layer, the conductive layer, and the insulating layer jointly form a partition structure;
S7: forming a light-emitting layer and a cathode layer in sequence at each pixel opening, so that the anode layer, the light-emitting layer, and the cathode layer jointly form a light-emitting element;
S8: forming m a first inorganic encapsulation layer on the side of the light-emitting element and the partition structure facing away from the substrate; and
S9: forming an organic encapsulation layer over the first inorganic encapsulation layer to obtain a fully encapsulated display panel.

The template layer may be a photoresist. The structural pattern corresponding to the bottom shape of the insulating layer may be formed using photolithography, followed by the deposition of the insulating layer material. Then after exposure and development, the structural pattern of the insulating layer for this embodiment is created, and then the template layer is removed.

### Second Embodiment

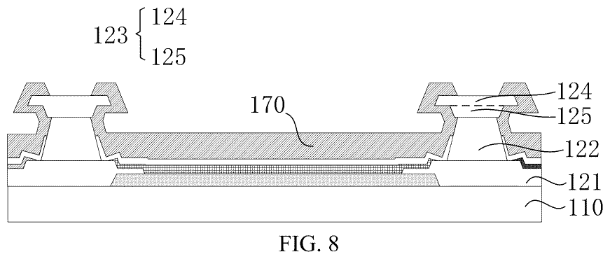

FIG. 8 is a schematic diagram illustrating film layers of a display panel according to a second embodiment of the present application. As shown in FIG. 8, in the second embodiment of the present application, the difference from the first embodiment lies in that the insulating layer 123 has a T-shaped cross-section in the thickness direction of the substrate 110. The first insulating portion 124 has an upright trapezoidal cross-section in the thickness direction of the substrate 110. The second insulating portion 125 has an inverted trapezoidal cross-section in the thickness direction of the substrate 110. This configuration also allows the first insulating portion 124 to be elevated, thereby increasing the distance between the first insulating portion 124 and the pixel defining layer 121. Moreover, in this case, the middle of the first insulating portion 124 is not hollowed out, which can enhance the overall strength of the insulating layer 123.

It should be noted that the limitations of the various steps involved in this solution are not to be interpreted to limit the order of the steps, under the premise of not affecting the implementation of the specific solution. The steps written earlier can be executed first, or later, or even at the same time with the steps written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising:
a substrate;
a plurality of partition structures, wherein each of the plurality of partition structures comprises a pixel defining layer, a conductive layer, and an insulating layer that are sequentially stacked, thus obtaining a plurality of pixel defining layers that are spaced apart from each other on the substrate; and
a plurality of light-emitting elements, wherein a pixel opening is formed between every two adjacent pixel defining layers thus obtaining a plurality of pixel openings, wherein the plurality of light-emitting elements are arranged in one-to-one correspondence within the plurality of pixel openings; and
a first inorganic encapsulation layer, disposed on and covering a side of the plurality of light-emitting elements and the plurality of partition structures facing away from the substrate;
wherein the insulating layer comprises a first insulating portion and a second insulating portion, wherein the second insulating portion is disposed on a side of a corresponding conductive layer facing away from a corresponding pixel defining layer, wherein the first insulating portion is disposed on a side of the second insulating portion facing away from the corresponding conductive layer;
wherein an orthographic projection of the first insulating portion on the substrate at least partially overlaps an orthographic projection of the second insulating portion on the substrate.

2. The display panel as recited in claim 1, wherein the first insulating portion comprises a first sub-insulating portion and a second sub-insulating portion that are disposed on the second insulating portion and that are spaced apart from each other;
wherein an orthographic projection of the first sub-insulating portion on the substrate partially overlaps an orthographic projection of the second insulating portion on the substrate; wherein an orthographic projection of the second sub-insulating portion on the substrate partially overlaps an orthographic projection of the second insulating portion on the substrate;
wherein the first sub-insulating portion, the second sub-insulating portion, and the second insulating portion jointly form a groove structure.

3. The display panel as recited in claim 2, wherein a cross section of each of the first sub-insulating portion and the second sub-insulating portion in a thickness direction of the substrate is of an upright trapezoidal structure;
wherein a cross section of the second insulating portion in the thickness direction of the substrate is of an inverted trapezoidal structure.

4. The display panel as recited in claim 3, wherein the first sub-insulating portion comprises a first inclined surface and a second inclined surface that are oppositely arranged, wherein the second sub-insulating portion comprises a third inclined surface and a fourth inclined surface that are oppositely arranged, wherein the second insulating portion comprises a fifth inclined surface and a fourth inclined surface that are oppositely arranged;
wherein when encapsulating the first inorganic encapsulation layer, an inclined encapsulation adhesion surfaces is formed on each of the first inclined surface, the fourth inclined surface, the fifth inclined surface, and the sixth inclined surface.

5. The display panel as recited in claim 4, wherein the conductive layer comprises a seventh inclined surface and an eighth inclined surface that are arranged opposite to each other, and wherein the fifth inclined surface of the second insulating portion is fitted with the seventh inclined surface of the conductive layer.

6. The display panel as recited in claim 2, wherein a thickness of the second insulating portion is greater than a thickness of the first sub-insulating portion or a thickness of the second sub-insulating portion, wherein a thickness of the first sub-insulating portion is equal to a thickness of the second sub-insulating portion;
wherein let the thickness of the second insulating portion be H, and let the thickness of each of the first sub-insulating portion and the second sub-insulating portion be h, then h≥½H.

7. The display panel as recited in claim 6, wherein an overlapping area between the first sub-insulating portion and the second insulating portion is equal to ½ of an area of an orthographic projection of the first sub-insulating portion on the substrate, and wherein an overlapping area between the second sub-insulating portion and the second insulating portion is also equal to ½ of an area of an orthographic projection of the second sub-insulating portion on the substrate.

8. The display panel as recited in claim 1, wherein an overall thickness of each of the plurality of partition structures lies in the range of 1.4 μm˜2 μm, and a thickness of the insulating layer lies in the range of 0.4 μm˜1 μm.

9. The display panel as recited in claim 1, wherein the insulating layer has a T-shaped cross-section in a thickness direction of the substrate;
wherein the first insulating portion has an upright trapezoidal cross-section in the thickness direction of the substrate, and wherein the second insulating portion has an inverted trapezoidal cross-section in the thickness direction of the substrate.

10. The display panel as recited in claim 2, wherein the second insulating portion comprises a first surface and a second surface that are oppositely arranged; wherein the corresponding conductive layer comprises a third surface and a fourth surface that are oppositely arranged;
wherein the third surface of the conductive layer is attached to the pixel defining layer, wherein the fourth surface of the conductive layer is attached to the second surface of the second insulating portion, wherein the first surface of the second insulating portion is attached to the first insulating portion;
wherein along the direction in which each of the plurality of partitions structures is arranged, a width of the second surface of the second insulating portion is equal to a width of the fourth surface of the corresponding conductive layer.

11. The display panel as claimed in claim 2, wherein each of the plurality of light-emitting elements comprises an anode layer, wherein the anode layer comprises a first end and a second end arranged opposite to each other;
wherein each of the plurality of pixel defining layers comprises a first portion and a second portion which are sequentially stacked along the thickness direction of the substrate, wherein one side of the first portion extends and overlaps the first end or the second end of the corresponding anode layer to form an overlapping portion;
wherein the overlapping portion combines with the second portion to jointly form a step structure, and wherein the light-emitting layer and the cathode layer partially overlap the step structure.

12. The display panel as recited in claim 7, wherein a width of each of the second portions is greater than a width of the first insulating portion of the insulating layer.

13. A method for manufacturing a display panel, comprising:
providing a substrate;
forming a plurality of anode layers that are spaced apart on the substrate;
forming a pixel defining layer between every two adjacent anode layers, so that a pixel opening is formed between the two adjacent pixel defining layers thus obtaining a plurality of pixel openings;
forming a conductive layer on the pixel defining layer;
forming a bottom shape structure of an insulating layer on the conductive layer using a template layer;
forming the insulating layer on the bottom shape structure, wherein the pixel defining layer, the conductive layer, and the insulating layer jointly form a partition structure;
forming a light-emitting layer and a cathode layer in sequence at each pixel opening, so that the anode layer, the light-emitting layer, and the cathode layer jointly form a light-emitting element;
forming a first inorganic encapsulation layer on a side of the light-emitting element and the partition structure facing away from the substrate; and
forming an organic encapsulation layer over the first inorganic encapsulation layer to obtain a fully encapsulated display panel.

14. A display device comprising a display panel, wherein the display panel comprises:
a substrate;
a plurality of partition structures, wherein each of the plurality of partition structures comprises a pixel defining layer, a conductive layer, and an insulating layer that are sequentially stacked, thus obtaining a plurality of pixel defining layers that are spaced apart from each other on the substrate; and
a plurality of light-emitting elements, wherein a pixel opening is formed between every two adjacent pixel defining layers thus obtaining a plurality of pixel openings, wherein the plurality of light-emitting elements are arranged in one-to-one correspondence within the plurality of pixel openings; and
a first inorganic encapsulation layer, covering a side of the plurality of light-emitting elements and the plurality of partition structures facing away from the substrate;
wherein the insulating layer comprises a first insulating portion and a second insulating portion, wherein the second insulating portion is disposed on a side of a corresponding conductive layer facing away from a corresponding pixel defining layer, wherein the first insulating portion is disposed on a side of the second insulating portion facing away from the corresponding conductive layer;
wherein an orthographic projection of the first insulating portion on the substrate at least partially overlaps an orthographic projection of the second insulating portion on the substrate.

15. The display device as recited in claim 14, wherein the first insulating portion comprises a first sub-insulating portion and a second sub-insulating portion that are disposed on the second insulating portion and are spaced apart from each other;
wherein an orthographic projection of the first sub-insulating portion on the substrate partially overlaps an orthographic projection of the second insulating portion on the substrate; wherein an orthographic projection of the second sub-insulating portion on the substrate partially overlaps an orthographic projection of the second insulating portion on the substrate;
wherein the first sub-insulating portion, the second sub-insulating portion, and the second insulating portion jointly form a groove structure.

16. The display device as recited in claim 15, wherein a cross section of each of the first sub-insulating portion and the second sub-insulating portion in a thickness direction of the substrate is of an upright trapezoidal structure;
wherein a cross section of the second insulating portion in the thickness direction of the substrate is of an inverted trapezoidal structure.

17. The display device as recited in claim 16, wherein the first sub-insulating portion comprises a first inclined surface and a second inclined surface that are oppositely arranged, wherein the second sub-insulating portion comprises a third inclined surface and a fourth inclined surface that are oppositely arranged, wherein the second insulating portion comprises a fifth inclined surface and a fourth inclined surface that are oppositely arranged;
wherein when encapsulating the first inorganic encapsulation layer, an inclined encapsulation adhesion surfaces is formed on each of the first inclined surface, the fourth inclined surface, the fifth inclined surface, and the sixth inclined surface.

18. The display device as recited in claim 17, wherein the conductive layer comprises a seventh inclined surface and an eighth inclined surface that are arranged opposite to each other, and wherein the fifth inclined surface of the second insulating portion is fitted with the seventh inclined surface of the conductive layer.

19. The display device as recited in claim 15, wherein a thickness of the second insulating portion is greater than a thickness of the first sub-insulating portion or a thickness of the second sub-insulating portion, wherein a thickness of the first sub-insulating portion is equal to a thickness of the second sub-insulating portion;
wherein let the thickness of the second insulating portion be H, and let the thickness of each of the first sub-insulating portion and the second sub-insulating portion be h, then h≥½H.

20. The display device as recited in claim 19, wherein an overlapping area between the first sub-insulating portion and the second insulating portion is equal to ½ of an area of an orthographic projection of the first sub-insulating portion on the substrate, and wherein an overlapping area between the second sub-insulating portion and the second insulating portion is also equal to ½ of an area of an orthographic projection of the second sub-insulating portion on the substrate.
